(19) United States
(12) Patent Application Publication
(10) Pub. No.: US 2021/0281182 A1
(43) Pub. Date: Sep. 9, 2021

(54) PHASE CURRENT CONTROL DEVICE FOR DAB CONVERTER, AND METHOD THEREFOR

(71) Applicant: KOREA ELECTRIC POWER CORPORATION, Naju-si (KR)

(72) Inventors: Jae-Han KIM, Daejeon (KR); Ju-Yong KIM, Daejeon (KR); Jin-Tae CHO, Daejeon (KR); Young-Pyo CHO, Daejeon (KR); Jee-Hoon JUNG, Ulsan (KR); Hyun-Jun CHOI, Ulsan (KR)

(21) Appl. No.: 16/336,829

(22) PCT Filed: Nov. 11, 2016
(86) PCT No.: PCT/KR2016/013024

§ 371 Date: Mar. 26, 2019

(30) Foreign Application Priority Data
Oct. 26, 2016 (KR) 10-2016-0140328

(51) Int. Cl. H02M 3/335; G01R 19/02; H02M 1/00

(52) U.S. Cl. CPC H02M 3/33584; H02M 1/0043; H02M 1/0009; G01R 19/02

(57) ABSTRACT

Disclosed are a phase current control device for a DAB converter and a method therefor. The device includes a DAB converter having at least one leg including a switching element, a phase current measuring unit for measuring a phase current for each of the legs, and a phase current phase controller for performing phase control by setting one of the phase currents of the respective legs as a reference phase current, comparing each of the other phase currents with the reference phase current to derive a phase difference for each of the phase currents, and compensating each of the phase currents for a corresponding one of the phase differences.

### CROSS-REFERENCE TO RELATED APPLICATIONS

This application claims the benefit under 35 U.S.C. Section 371, of PCT International Application No. PCT/KR2016/013024, filed on Nov. 11, 2016, which claimed priority to Korean Patent Application No. KR 10-2016-0140328, filed on Oct. 26, 2016, the disclosures of which are hereby incorporated by the references.

### TECHNICAL FIELD

The present invention relates to a phase current control device for a DAB converter and a method therefor. More particularly, the present invention relates to a phase control device for a DAB converter and a method therefor, the device and method being capable of minimizing a phase current imbalance when a phase current imbalance between legs of a DAB converter is detected, by setting a specific phase current as a reference phase current, comparing each of the other phase currents with the reference phase current, and compensating each of the phase currents for a phase difference.

### BACKGROUND ART

When transmitting power from a medium/high voltage DC power system such as a medium voltage direct current (MVDC) system, a low voltage direct current (LVDC) system, and a solid-state transformer (SST) system to a low voltage DC power system, a power converter that converts a higher voltage of input power to a lower voltage of output power is required.

To this end, a high-voltage semiconductor switch is required on the input side and a large-current semiconductor switch is required on the output side. However, since the maximum rating of commercially available semiconductor devices is limited, it is difficult to achieve sufficient power conversion performance with a single power converter.

In order to solve this problem, a power converter in which a plurality of power conversion devices is connected in series/parallel with each other is used. A typical example of such a power converter is a modular multilevel converter (MMC). An MMC consists of a plurality of converters connected in series, thereby generating a plurality of DC output voltages from an AC input voltage. In this case, it is possible to use a switching element with a relatively low rated capacity in a power system.

However, in order to implement an intelligent transformer, an isolated bidirectional converter technology is required. Bidirectional converters are classified into a non-isolated type and an isolated type depending on the type of insulation. In most power systems, an isolated converter is preferred due to the operation stability.

Isolated bidirectional converters are currently intensively being studied. Isolated bidirectional converters are mainly classified into a combination type in which a phase-shifted zero voltage switching converter and an isolated boost converter are combined, a dual active bridge (DAB) converter type, and an LLC resonance converter type.

In recent years, the power capacity required for isolated bidirectional converters is gradually increasing. Therefore, three-phase bidirectional converters are actively being researched due to the advantages of reducing the current burden, allowing a convenient selection of switches, and reducing the volume of passive elements by using an interleaving technique.

A typical example of a conventional three-phase bidirectional converter is a DAB converter. A DAB converter is suitable for applications using high power/high current bidirectional topology because current flows as three phase currents in the DAB converter. In addition, a DAB converter is suitable for bidirectional power control because it uses a phase shift technique to perform make-before-break switching.

FIG. 1 is a diagram illustrating actual modeling values of a transformer and a coupling inductor in a DAB converter.

Referring to FIG. 1, due to errors of the transformer and the coupling inductor, which are actually likely to occur in a three-phase DAB converter, line resistance, line impedance, leakage inductance, and magnetizing inductance are not actually identical among different phases of a transformer. Since the parameters are not identical among the phases in a transformer, a phase current imbalance occurs.

In particular, when there is a considerable phase current imbalance in a transformer, the transformer is likely to be saturated. When a transformer is saturated, the impedance is reduced, resulting in that the current flows only toward one side. This deteriorates operation stability or shortens the life span of a transformer, and causes a failure of a stack. Regarding this problem, one possible solution is to increase the capacity of a transformer. However, this method has a disadvantage of increasing the overall volume of a DAB converter or increasing the fabrication cost.

Therefore, for conventional three-phase DAB converters, it is required to secure operation stability by preventing saturation of a transformer.

### DISCLOSURE

### Technical Problem

An objective of the present invention is to provide a phase current control device for a DAB converter and a method therefor, the device and method being capable of minimizing a phase current imbalance when a phase current imbalance between legs of a DAB converter is detected, by setting a specific phase current as a reference phase current, comparing each of the other phase currents with the reference phase current, and compensating each of the phase currents for a phase difference.

### Technical Solution

According to one embodiment of the present invention, there is provided a phase current control device for a DAB converter, the device including: a DAB converter having at least one leg including a switching element; a phase current measuring unit for measuring a phase current for each of the legs; and a phase current phase controller for performing phase control by setting one of the phase currents of the respective legs as a reference phase current, comparing each of the other phase currents with the reference phase current, and compensating each of the phase currents for a phase difference.

The phase current measuring unit may determine a root mean square (RMS) for each of the phase currents, and the phase current phase controller may determine a phase control method on the basis of an RMS deviation for each of the phase currents.

The DAB converter may include a first-first leg, a first-second leg, and a first-third leg on a primary side, and a second-first leg, a second-second leg, and a second-third leg on a secondary side. The phase current phase controller may compensate, for a phase difference, each of a phase current flowing between the first-first leg and the second-first leg; a phase current flowing between the first-second leg and the second-second leg; and a phase current between the first-third leg and the second-third leg.

According to one embodiment of the present invention, there is provided a phase current control method for a DAB converter, the method including: measuring a phase current per leg of a DAB converter; setting one of the phase currents of the respective legs as a reference current phase; comparing each of the other phase currents with the reference phase current to derive a phase shift compensation value for each of the phase currents; and controlling a phase of each of the phase currents by using a corresponding one of the phase shift compensation values.

The method may further include checking whether there is a phase current imbalance between each of the legs of the DAB converter, in which the checking is performed after the measuring.

### Advantageous Effects

When a phase current imbalance between legs of a DAB converter is detected, the present invention can minimize the phase current imbalance by setting a specific phase current as a reference phase current, comparing each of the other phase currents with the reference phase current, and compensating each of the phase currents for a phase difference.

With the use of the present invention, it is not necessary to increase the rating of a transformer or apply a transformer protection technique to resolve the problem of a current imbalance which is likely to occur in a transformer of a conventional three-phase DAB converter.

In addition, the present invention can reduce a current imbalance without increasing cost, thereby increasing device reliability and device availability and reducing cost.

In addition, when a phase current imbalance occurs due to a difference in leakage inductance, magnetizing inductance, or line resistance of a transformer, the present invention can reduce a current imbalance between legs because it is possible to increase or reduce the magnitude of an electric current during conduction of each leg by using an independent control variable.

### DESCRIPTION OF DRAWINGS

FIG. 1 is a diagram illustrating actual modeling values of a transformer and a coupling inductance in a DAB converter;

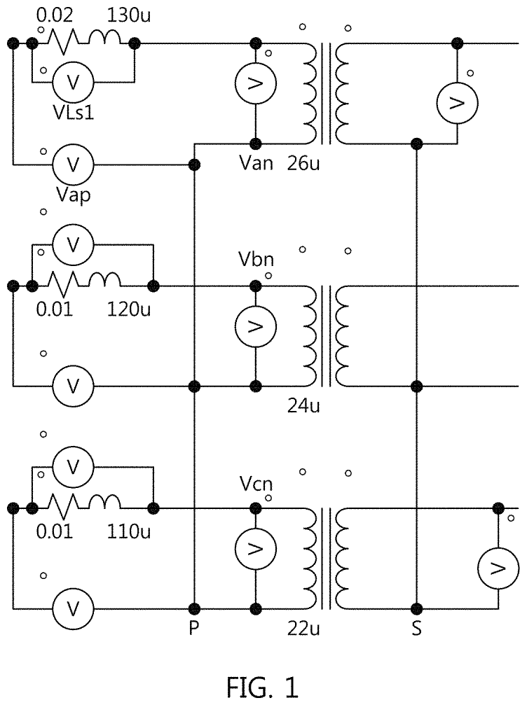

FIG. 2 is a diagram illustrating a phase current control device for a DAB converter according to one embodiment of the present invention;

FIG. 3A is a graph illustrating a result of comparison of single-phase waveforms according to phase current phase control methods;

FIG. 3B is a graph illustrating comparison results of the overall RMS waveforms according to phase current phase control methods;

FIG. 4 is a diagram illustrating a phase control method for a DAB converter, according to one embodiment of the present invention; and

FIG. 5 is a view illustrating a specific example of Step S204 of FIG. 4.

### BEST MODE

In order to help thorough understanding of the present invention, the best mode of the present invention will be described with reference to the accompanying drawings. The mode of the present invention described below may be modified into various forms, so that the scope of the present invention should not be construed as being limited to the mode described in detail below. The best mode is provided to more fully describe the present invention to those skilled in the art. Therefore, throughout the drawings, the shapes and the like of elements may be exaggerated for the purpose of clarity. It should be noted that in the drawings, like elements are denoted by like reference numerals. Detailed descriptions of known features and configures that are likely to obscure the gist of the present invention will be omitted.

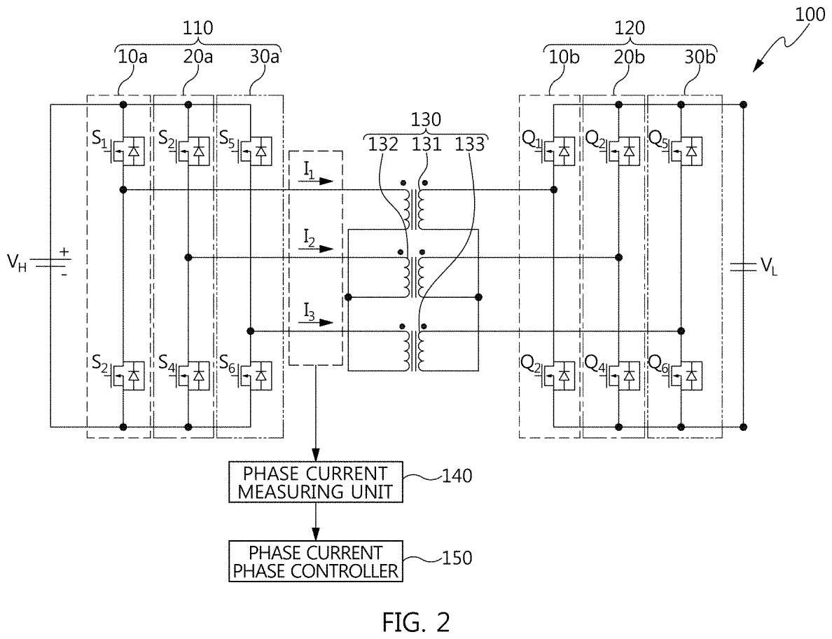

FIG. 2 is a diagram illustrating a phase current control device for a DAB converter, according to one embodiment of the present invention.

Referring to FIG. 2, a “phase current control device for a DAB converter” (hereinafter referred to as a “phase current control device” 100), according to one embodiment of the present invention, includes a DAB converter 110 to 130, a phase current measuring unit 140, and a phase current phase controller 150. Here, the DAB converter 110 to 130 includes a first power supply circuit 110, a second power supply circuit 120, and a transformer 130.

First, the DAB converter 110 to 130 is configured such that voltage sources VH and VL are positioned on left and right sides in the drawing, two full-bridge converters respectively referred to as the first power supply circuit 110 and the second power supply circuit 120 are set at a fixed duty of 50% via the transformer 130, and the flow of an electric current is controlled by using a phase difference between the primary side and the secondary side. In the DAB converter 110 to 130, three phase currents flow and the output voltage are controlled on the basis of a phase shift.

Specifically, the components of the DAB converter 110 to 130 are as follows.

First, the first power supply circuit 110 includes primary bridge switching elements 51 to S6. The first power supply circuit 110 has three legs. That is, the switching elements 51 and S2 on the primary side constitute a first leg (hereinafter, referred to as a “first-first leg”) 10a, the switching elements S3 and S4 on the primary side constitute a second leg (hereinafter, referred to as a “first-second leg”) 20a, and the switching elements S5 and S6 on the primary side constitute a third leg (hereinafter, referred to as a first-third leg”) 30a.

Similarly, the second power supply circuit 120 includes secondary bridge switching elements Q1 to Q6. The second power supply circuit 120 has three legs. That is, the switching elements Q1 and S2 on the secondary side constitute a first leg (hereinafter, referred to as a “second-first leg”) 10b, the switching elements Q3 and S4 on the secondary side constitute a second leg (hereinafter, referred to as a “second-second leg”) 20b, and the switching elements Q5 and S6 on the secondary side constitute a third leg (hereinafter, referred to as a second-third leg”) 30b.

Here, each of the primary bridge switching elements 51 to S6 and the secondary bridge switching elements Q1 to Q6 is a metal oxide semiconductor field effect transistor (MOSFET) or an insulated gate bipolar transistor (IGBT).

Next, the transformer 130 is positioned between the first power supply circuit 110 and the second power supply circuit 120. The transformer 30 is made up of first to third transformers 131 to 133.

In the first transformer 131, a first end of a first winding is connected between the primary switching elements 51 and S2, and a first end of a second winding is connected between the secondary switching elements Q1 and Q2. That is, the first transformer 131 is configured such that the first end of the first winding is connected with the first-first leg 10a and the second-first leg 10b. Here, the first-first leg 10a and the first-second leg 10b form a pair of legs for independent phase current control.

Similarly, in the second transformer 132, a first end of a first winding is connected between the primary switching elements S3 and S4, and a first end of a second winding is connected between the secondary switching elements Q3 and Q4. That is, the first transformer 132 is configured such that the first end of the first winding is connected with the first-second leg 20a and the second-second leg 20b. Here, the first-second leg 20a and the second-second leg 20b form a pair of legs for independent phase current control.

Similarly, in the third transformer 133, a first end of a first winding is connected between the primary switching elements S5 and S6, and a first end of a second winding is connected between the secondary switching elements Q5 and Q6. That is, the third transformer 133 is configured such that the first end of the first winding is connected with the first-third leg 30a and the second-third leg 30b. Here, the first-third leg 30a and the second-third leg 30b form a pair of legs for independent phase current control.

The second ends of the first windings of the first to third transformers 131, 132, and 133 are connected with each other and the second ends of the second windings of the first to third transformers 131, 132, and 133 are connected with each other.

The phase current measuring unit 140 measures a phase current output from the legs of the primary side. That is, the phase current measuring unit 140 measures a phase current I₁ output from the first-first leg 10a, a phase current I₂ output from the first-second leg 20a, and a phase current I₃ output from the first-third leg 30a. The phase current measuring unit 140 obtains the root mean square (RMS) values of the phase currents output from the respective legs and provides the RMS values to the phase current phase controller 150.

The phase current phase controller 150 checks an RMS deviation for each phase current, delivered from the phase current measuring unit 140, and controls the output voltage through phase shifting of each of the phase currents to reduce the RMS deviation of each phase current. Here, the presence of an RMS deviation between phase currents indicates that a phase current imbalance has occurred. When the RMS deviation is within a predetermined range, the phase current phase controller 150 determines that a phase current imbalance has not occurred. However, when the RMS deviation is out of the predetermined range, the phase current phase controller 150 determines that a phase current imbalance has occurred.

The phase current phase controller 150 can minimize the imbalance in phase current by setting one of the phase currents as a reference phase current, comparing each of the other phase currents with the reference phase current to derive a phase difference, and compensating each of the phase current for the phase difference.

Hereinafter, for convenience of explanation, a phase current to be a reference to determine a phase shift will be referred to as a “reference phase current”, and each of the other phase currents to be compared with the reference phase current for phase compensation is referred to as a “comparative phase current”. A phase shift value for compensating for a phase difference is referred to as a “phase shift compensation value”. In FIG. 2, the reference phase current is a phase current I₁ flowing between the first-first leg 10a and the second-first leg 10b, and the comparative phase currents include a comparative phase current I₂ flowing between the first-second leg 20a and the second-second leg 20b and a phase current I₃ between the first-third leg 30a and the second-third leg 30b. In this case, the phases of the reference phase current I₁, the comparative phase current I₂, and the comparative phase current I₃ are assumed to be φ, σ, τ, respectively. The phase shift compensation value for the comparative phase current I₂ is assumed to be α, and the phase shift compensation value for the comparative phase current I₃ is assumed to be β. The phase shift compensation value α for the comparative phase current I₂ is a difference between the phase φ of the reference phase current I₁ and the phase a of the comparative phase current I₂, and the phase shift compensation value β is a difference between the phase φ of the reference phase current I₁ and the phase τ of the comparative phase current I₃.

When an RMS deviation occurs between each of the phase currents, that is, when a phase current imbalance occurs, the phase current phase controller 150 performs independent phase control for each leg by reflecting a phase shaft for a corresponding one of the comparative phase currents on the phase of the reference phase current rather than performing equal phase control in which all of the phase currents including the reference phase current and the comparative phase currents are adjusted to be in the same phase (i.e., the phase φ of the reference phase current). That is, the phase current phase controller 150 performs phase control on the reference phase current I₁ such that the reference phase current I₁ is in a phase of φ. That is, the phase current I₁ flowing between the first-first leg 10a and the second-first leg 10b is controlled to be in the phase φ. Next, the phase current phase controller 150 performs phase control on the comparative phase current I₂ by reflecting a phase shift compensation value σ on the phase φ. That is, the phase current I₂ flowing between the first-second leg 20a and the second-second leg 20b is controlled to be in a phase of φ plus or minus α. Next, the phase current phase controller 150 performs phase control on the comparative phase current I₃ by reflecting a phase shift compensation value β on the phase φ. That is, the phase current I₃ flowing between the first-third leg 30a and the second-third leg 30b is controlled to be in a phase of φ plus or minus β.

The reflecting a phase shift compensation value on the phase of the reference phase current is performed in a manner described below. That is, the phase current phase controller 150 compares the magnitude of the reference phase current with the magnitude of each of the comparative phase currents, and adds or subtracts a predetermined phase shift compensation value to or from the phase of the reference phase current, thereby correcting the phase of the corresponding comparative phase current. More specifically, when the reference phase current 11 is higher than the comparative phase current I₂ (that is, I₁>I₂), the phase current phase controller 150 performs phase control such that the comparative phase current I₂ is in a phase greater than the phase φ of the reference phase current by the phase shift compensation value α. Conversely, when the reference phase current I₁ is lower than the comparative phase current I₂ (that is, I₁<I₂), the phase current phase controller 150 performs phase control such that the comparative phase current I₂ is in a phase less than the phase φ of the reference phase current I₁ by the phase shift compensation value α. Similarly, when the reference phase current I₁ is larger than the comparative phase current I₃ (that is, I₁>13), the phase current phase controller 150 performs phase control such that the comparative phase current I₃ is in a phase greater than the phase φ of the reference phase current I₁ by the phase shift compensation value β. Conversely, when the reference phase current I₁ is smaller than the comparative phase current I₃ (that is, I₁<I₃), the phase current phase controller 150 performs phase control such that the comparative phase current I₃ is in a phase less than the phase φ of the reference phase current I₁ by the phase shift compensation value β.

As described above, the phase current phase controller 150 controls the output voltage not by applying an equal phase shift to all of the phase currents flowing through the respective legs but by independently applying different phase shifts on the phase currents flowing through the respective legs when a phase current imbalance occurs. As described above, the phase current control device 100 can reduce the phase current imbalance by minimizing a phase difference between the phase currents of the respective legs.

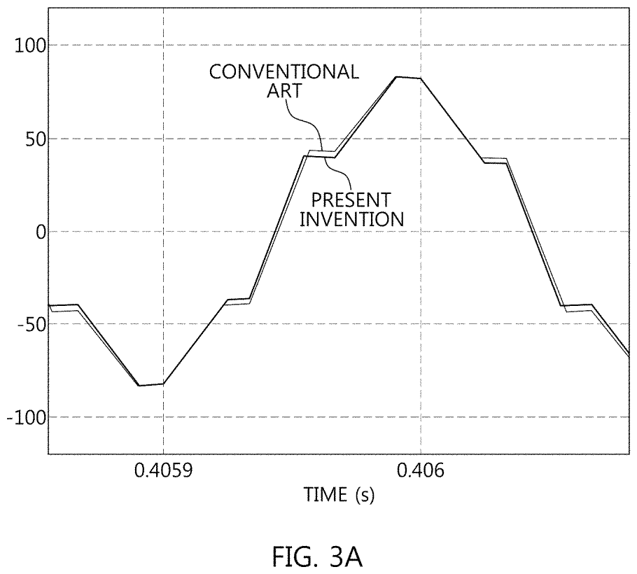

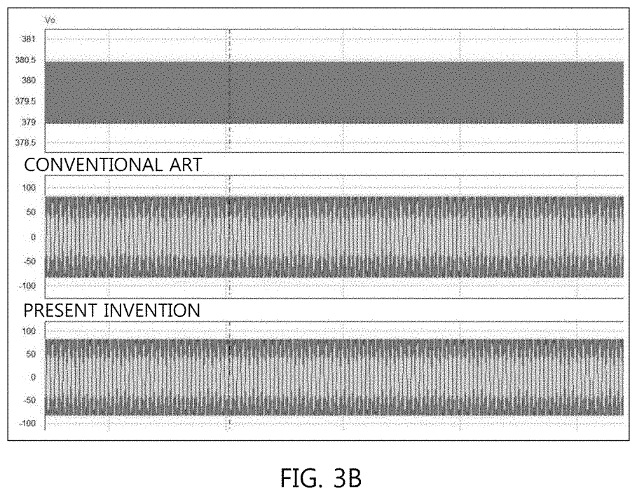

FIG. 3A is a graph showing a result of comparison between single-phase waveforms obtained by applying different phase current control methods, and FIG. 3B is a graph showing a result of comparison between overall RMS waveforms obtained by applying different phase current control methods. [Table 1] shows the overall RMS comparison between the phase current control based on independent phase shifts, according to the present invention, and a conventional phase current control based on an equal phase shift.

TABLE 1

| Classification | RMS value |
|---|---|
| Vo | 3.7999707e+002 |
| Present invention - reference phase current I₁ | 5.4046524e+001 |
| Present invention - comparative phase current I₂ | 5.3656805e+001 |
| Present invention - comparative phase current I₃ | 5.3974511e+001 |
| Conventional art - reference phase current I₁ | 5.3055668e+001 |
| Conventional art - comparative phase current I₂ | 5.3988887e+001 |
| Conventional art - comparative phase current I₃ | 5.4943004e+001 |

Referring to FIGS. 3A and 3B and Table 1, it can be seen that the independent phase shift control for phase current, according to the present invention, has a reduced RMS as compared to the equal phase shift control for phase current according to the conventional art. That is, the “independent phase shift control for phase current” according to the present invention can reduce an RMS deviation by about 75% as compared to a conventional method, thereby reducing the imbalance between the phase currents. FIG. 3A is a diagram illustrating a single-phase waveform of the comparative phase current I₃.

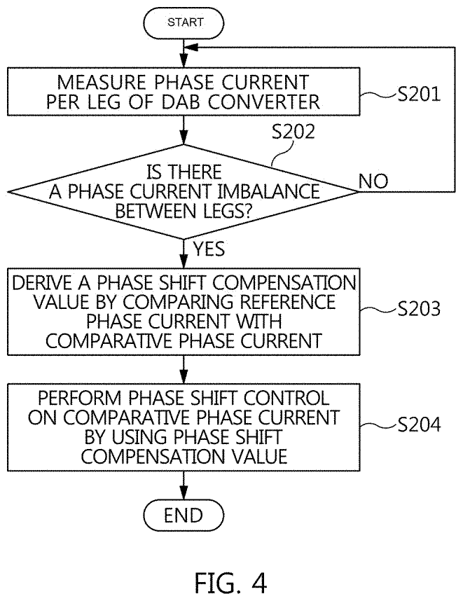

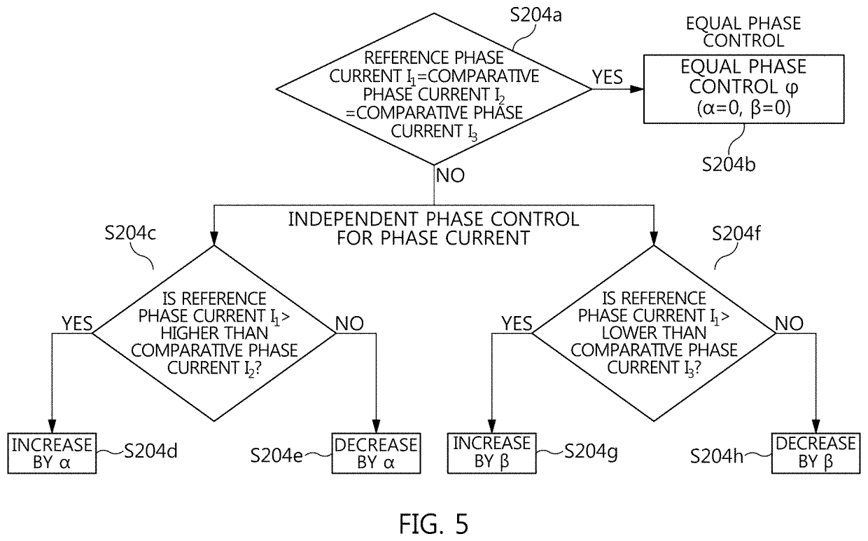

FIG. 4 is a diagram illustrating a phase current control method for a DAB converter, according to one embodiment of the present invention, and FIG. 5 is a diagram illustrating the details of Step S204 of FIG. 4.

First, a phase current measuring unit 140 measures the phase currents (that is, reference phase current and comparative phase currents) of respective legs of a DAB converter 110 to 130 at Step S201. At this time, the phase current measuring unit 140 obtains an RMS of the phase current for per leg.

The phase current phase controller 150 determines whether there is an imbalance between the phase currents of the respective legs using the RMS values of the phase currents obtained by the phase current measuring unit 140 in step S202. That is, the phase current phase controller 150 can confirm whether there is an imbalance in phase current among legs by checking whether there is an RMS deviation among the phase currents of the respective legs.

When the RMS deviation is within a predetermined range, the phase current phase controller 150 performs phase control such that all the phase currents of the respective legs are in the same phase. In this case, it is determined that the RMS deviation is not significant because the RMS deviation is within the predetermined range, and the phase currents of the respective legs are all controlled to be in the same phase.

Next, when the RMS deviation is out of the predetermined range, the phase current phase controller 150 performs the independent phase control in which the phase currents of the respective legs are independently controlled. That is, the phase current phase controller 150 compares a reference phase current and each of the comparative phase currents to derive phase shift compensation values for the respective comparative phase currents in Step S203, and controls the phase shifts for the respective comparative phase currents using the derived phase shift compensation values, respectively, in Step S204.

Referring to FIG. 5, in step S204, the phase current phase controller 150 compares the magnitude of the reference phase current I₁ with each of the magnitudes of the comparative phase currents I₂ and I₃ (S204a). When the reference current I₁ and the comparative phase currents I₂ and I₃ are all have the same magnitude, the phase current phase controller 150 performs phase control such that all of the phase currents are controlled to be in the same phase. In this case, phase shift compensation values α and β are zero (S204b).

On the other hand, when the magnitude of the reference phase current I₁ is not the same as either of the magnitudes of the comparative phase currents I₂ and I₃, the phase current phase controller 150 performs the independent phase control in which the phase shift compensation values α and β for the respective comparative phase currents are added or subtracted to or from the phase of the reference phase current.

That is, when the reference phase current I₁ is higher than the comparative phase current I₂ (that is, I₁>I₂) (S204c), the phase current phase controller 150 performs phase control such that the phase of the comparative phase current I₂ becomes greater than the phase φ of the reference phase current by the phase shift compensation value α (S204d). Conversely, when the reference phase current I₁ is lower than the comparative phase current I₂ (that is, I₁<I₂) (S204c), the phase current phase controller 150 performs phase control such that the phase of the comparative phase current I₂ becomes less than the phase φ of the reference phase current I₁ by the phase shift compensation value α (S204e). Similarly, when the reference phase current I₁ is higher than the comparative phase current I₃ (that is, I₁>I₃) (S204f), the phase current phase controller 150 performs phase control such that the phase of the comparative phase current I₃ becomes greater than the phase φ of the reference phase current I₁ by the phase shift compensation value β (S204g). Conversely, when the reference phase current I₁ is lower than the comparative phase current I₃ (that is, I₁<13), the phase current phase controller 150 performs phase control such that the phase of the comparative phase current I₃ becomes less than the phase φ of the reference phase current I₁ by the phase shift compensation value β.

It will be appreciated by those skilled in the art that the embodiments of the present invention described above are merely illustrative and that various modifications and equivalent embodiments are possible without departing from the scope and spirit of the invention. Therefore, it will be appreciated that the present invention is not limited to the form set forth in the foregoing description. Accordingly, the true scope of technical protection of the present invention should be determined by the technical idea of the appended claims. It is also to be understood that the present invention covers all modifications, equivalents, and alternatives falling within the spirit and the scope of the present invention as defined by the appended claims.

1. A phase current control device for a DAB converter, the device comprising:
a DAB converter having at least one leg including a switching element;
a phase current measuring unit for measuring a phase current for each of the legs; and
a phase current phase controller for performing phase control by setting one of the phase currents of the respective legs as a reference phase current, comparing each of the other phase currents with the reference phase current, and compensating each of the phase currents for a phase difference.

2. The phase current control device according to claim 1, wherein the phase current measuring unit determines a root mean square (RMS) for each of the phase currents, and the phase current phase controller determines a phase control method on the basis of an RMS deviation for each of the phase currents.

3. The phase current control device according to claim 1, wherein the DAB converter includes a first-first leg, a first-second leg, and a first-third leg on a primary side and a second-first leg, a second-second leg, and a second-third leg on a secondary side, and
the phase current phase controller performs the phase control by compensating for a phase difference on each of a phase current flowing between the first-first leg and the second-first leg, a phase current flowing between the first-second leg and the second-second leg, and a phase current flowing between the first-third leg and the second-third leg.

4. A phase current control method for a DAB converter, the method comprising:
measuring a phase current per leg of a DAB converter;
deriving a phase shift compensation value for each of the phase currents by setting one of the phase currents of the respective legs as a reference phase current and comparing each of the other phase currents of the respective legs with the reference phase current; and
controlling phases of the respective current phases on the basis of the phase shift compensation values.

5. The phase current control method according to claim 4, further comprising checking whether there is a phase current imbalance between the legs of the DAB converter, wherein the checking is performed after the measuring.
